(19) United States
(12) Patent Application Publication
(10) Pub. No.: US 2024/0036462 A1
(43) Pub. Date: Feb. 1, 2024

(54) PELLICLE FOR EUV LITHOGRAPHY MASKS AND METHODS OF MANUFACTURING THEREOF

(71) Applicant: TAIWAN SEMICONDUCTOR MANUFACTURING COMPANY, LTD., Hsinchu (TW)

(72) Inventors: Pei-Cheng HSU, Taipei (TW); Ting-Pi Sun, Taichung City (TW); Hsin-Chang Lee, Zhubei City (TW)

(21) Appl. No.: 18/114,126

(22) Filed: Feb. 24, 2023

Related U.S. Application Data
(60) Provisional application No. 63/392,772, filed on Jul. 27, 2022.

(51) Int. Cl. G03F 1/64; G03F 1/22; C01B 32/168

(52) U.S. Cl. CPC G03F 1/64; G03F 1/22; C01B 32/168; C01B 2202/06

(57) ABSTRACT

In a method of manufacturing a pellicle for an extreme ultraviolet (EUV) photomask, a nanotube layer including a plurality of carbon nanotubes is formed, the nanotube layer is attached to a pellicle frame, and a Joule hearting treatment is performed to the nanotube layer by applying electric current through the nanotube layer.

### RELATED APPLICATIONS

This application claims priority of U.S. Provisional Patent Application No. 63/392,772 filed on Jul. 27, 2022, the entire contents of which are incorporated herein by reference.

### BACKGROUND

A pellicle is a thin transparent film stretched over a frame that is glued over one side of a photo mask to protect the photo mask from damage, dust and/or moisture. In extreme ultraviolet (EUV) lithography, a pellicle having a high transparency in the EUV wavelength region, a high mechanical strength and a low or no contamination is generally required. An EUV transmitting membrane is also used in an EUV lithography apparatus instead of a pellicle.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B show pellicles for an EUV photo mask in accordance with embodiments of the present disclosure.

FIGS. 2A, 2B, 2C and 2D show various views of multiwall nanotubes in accordance with embodiments of the present disclosure.

FIGS. 3A, 3B and 3C show a manufacturing process of a network membrane in accordance with an embodiment of the present disclosure.

FIG. 3D shows a manufacturing process of a network membrane, and FIG. 3E shows a flow chart thereof in accordance with an embodiment of the present disclosure.

FIGS. 4A and 4B show a cross sectional view and a plan (top) view of one of the various stages for manufacturing a pellicle for an EUV photo mask in accordance with an embodiment of the present disclosure.

FIGS. 5A and 5B show a cross sectional view and a plan (top) view of one of the various stages for manufacturing a pellicle for an EUV photo mask in accordance with an embodiment of the present disclosure.

FIGS. 6A and 6B show a cross sectional view and a plan (top) view of one of the various stages for manufacturing a pellicle for an EUV photo mask in accordance with an embodiment of the present disclosure.

FIGS. 7A and 7B show flow chart for manufacturing a pellicle for an EUV photo mask in accordance with embodiments of the present disclosure.

FIGS. 8A, 8B, 8C and 8D show various views of a Joule heating apparatus and process for a pellicle or a pellicle membrane in accordance with embodiments of the present disclosure.

FIG. 9 shows a schematic view of a Joule heating apparatus and process for a pellicle or a pellicle membrane in accordance with an embodiment of the present disclosure.

FIG. 10 shows a schematic view of a Joule heating apparatus using induction heating and process for a pellicle or a pellicle membrane in accordance with an embodiment of the present disclosure.

FIG. 11 shows schematic views illustrating formation of a bundle of nanotubes according to an embodiment of the present disclosure.

FIG. 12 shows schematic views illustrating removal or conversion of amorphous carbon according to an embodiment of the present disclosure.

FIGS. 13A, 13B, 13C, 13D and 13E show various views of removal of residual catalysts and formation of a bundle of nanotubes in accordance with embodiments of the present disclosure

FIG. 14 is a flow chart for treating a pellicle for an EUV photo mask in accordance with embodiments of the present disclosure.

FIGS. 15A, 15B, 15C, 15D, 15E and 15F show an EUV lithography process in accordance with embodiments of the present disclosure.

FIGS. 16A, 16B, 16C, 16D and 16E show diagrams of a pellicle in accordance with some embodiments of the present disclosure.

FIG. 17A shows a flowchart of a method making a semiconductor device, and FIGS. 17B, 17C, 17D and 17E show a sequential manufacturing operation of a method of making a semiconductor device in accordance with embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detained description thereof may be omitted.

EUV lithography is one of the crucial techniques for extending Moore's law. However, due to wavelength scaling from 193 nm (ArF) to 13.5 nm, the EUV light source suffers from strong power decay due to environmental adsorption. Even though a stepper/scanner chamber is operated under vacuum to prevent strong EUV adsorption by gas, maintaining a high EUV transmittance from the EUV light source to a wafer is still an important factor in EUV lithography.

A pellicle generally requires a high transparency and a low reflectivity. In UV or DUV lithography, the pellicle film is made of a transparent resin film. In EUV lithography, however, a resin based film would not be acceptable, and a non-organic material, such as a polysilicon, silicide or metal film, is used.

Carbon nanotubes (CNTs) are one of the materials suitable for a pellicle for an EUV reflective photo mask, because CNTs have a high EUV transmittance of more than 96.5%. Generally, a pellicle for an EUV reflective mask requires the following properties: (1) Long life time in a hydrogen radical rich operation environment in an EUV stepper/scanner; (2) Strong mechanical strength to minimize the sagging effect during vacuum pumping and venting operations; (3) A high or perfect blocking property for particles larger than about 20 nm (killer particles); and (4) A good heat dissipation to prevent the pellicle from being burnt out by EUV radiation. Other nanotubes made of a non-carbon based material are also usable for a pellicle for an EUV photo mask. In some embodiments of the present disclosure, a nanotube is a one dimensional elongated tube having a dimeter in a range from about 0.5 nm to about 100 nm.

In the present disclosure, a pellicle for an EUV photo mask includes a network membrane having a plurality of nanotubes that form a mesh structure. Further, a method of treating the network membrane to remove contaminants and to increase mechanical strength is also disclosed.

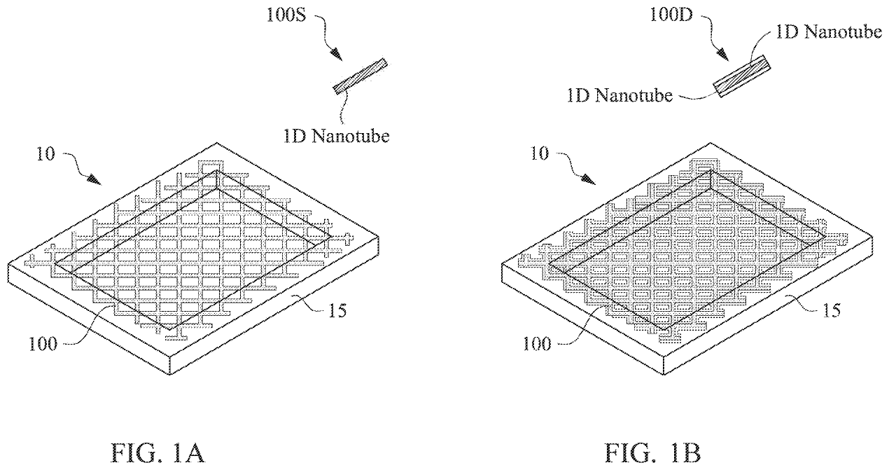

FIGS. 1A and 1B show EUV pellicles 10 in accordance with an embodiment of the present disclosure. In some embodiments, a pellicle 10 for an EUV reflective mask includes a main network membrane 100 disposed over and attached to a pellicle frame 15. In some embodiments, as shown in FIG. 1A, the main network membrane 100 includes a plurality of single wall nanotubes 100S, and in other embodiments, as shown in FIG. 1B, the main network membrane 100 includes a plurality of multiwall nanotubes 100D. In some embodiments, the single wall nanotubes are carbon nanotubes. In some embodiments, some of the single wall nanotubes form a bundle of nanotubes by being closely attached to each other.

In some embodiments, a multiwall nanotube is a co-axial nanotube having two or more tubes co-axially surrounding an inner tube(s). In some embodiments, the main network membrane 100 includes only one type of nanotubes (single wall/multiwall, or material) and in other embodiments, different types of nanotubes form the main network membrane 100. In some embodiments, the multiwall nanotubes are multiwall carbon nanotubes. In some embodiments, some of the multiwall nanotubes form a bundle of nanotubes by being closely attached to each other.

In some embodiments, a pellicle (support) frame 15 is attached to the main network membrane 100 to maintain a space between the main network membrane of the pellicle and an EUV mask (pattern area) when mounted on the EUV mask. The pellicle frame 15 of the pellicle is attached to the surface of the EUV photo mask with an appropriate bonding material. In some embodiments, the bonding material is an adhesive, such as an acrylic or silicon based glue or an A-B cross link type glue. The size of the frame structure is larger than the area of the black borders of the EUV photo mask so that the pellicle covers not only the circuit pattern area of the photo mask but also the black borders.

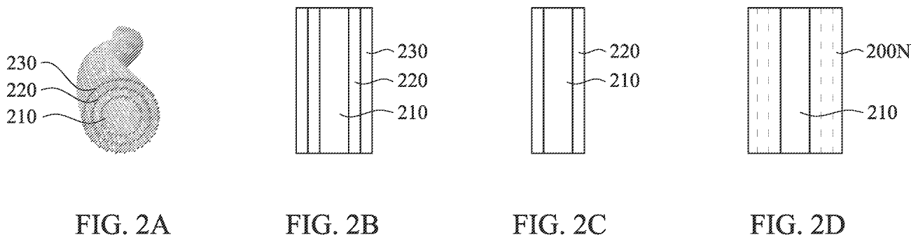

FIGS. 2A, 2B, 2C and 2D show various views of multiwall nanotubes in accordance with embodiments of the present disclosure.

In some embodiments, the nanotubes in the main network membrane 100 include multiwall nanotubes, which are also referred to as co-axial nanotubes. FIG. 2A shows a perspective view of a multiwall co-axial nanotube having threes tubes 210, 220 and 230 and FIG. 2B shows a cross sectional view thereof. In some embodiments, the inner tube 210 and outer tubes 220 and 230 are carbon nanotubes. In other embodiments, one of more of the inner or two outer tubes are non-carbon based nanotubes, such as boron nitride nanotubes.

The number of tubes of the multiwall nanotubes is not limited to three. In some embodiments, the multiwall nanotube has two co-axial nanotubes as shown in FIG. 2C, and in other embodiments, the multiwall nanotube includes the innermost tube 210 and the first to N-th nanotubes including the outermost tube 200N, where N is a natural number from 1 to about 20, as shown in FIG. 2D. In some embodiments, N is up to 10 or up to 5. In some embodiments, at least one of the first to the N-th outer layers is a nanotube coaxially surrounding the innermost nanotube 210. In some embodiments, all the innermost tube 210 and the first to the N-th outer layers are carbon nanotubes. In other embodiments, one or more of the tubes are non-carbon based nanotubes.

In some embodiments, a diameter of the innermost nanotube is in a range from about nm to about 20 nm and is in a range from about 1 nm to about 10 nm in other embodiments. In some embodiments, a diameter of the multiwall nanotubes (i.e., diameter of the outermost tube) is in a range from about 3 nm to about 40 nm and is in a range from about 5 nm to about 20 nm in other embodiments. In some embodiments, a length of the multiwall nanotube is in a range from about 0.5 μm to about 50 μm and is in a range from about 1.0 μm to about 20 μm in other embodiments.

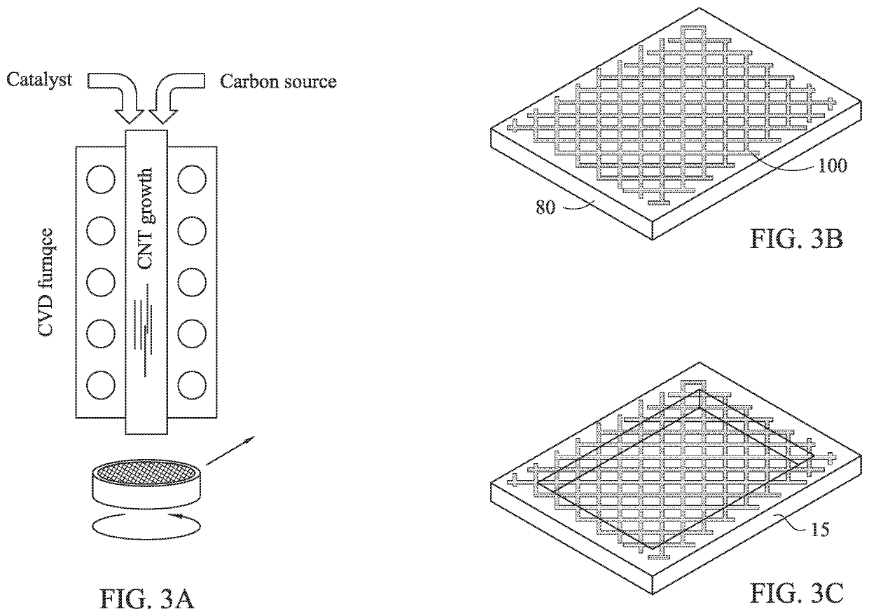

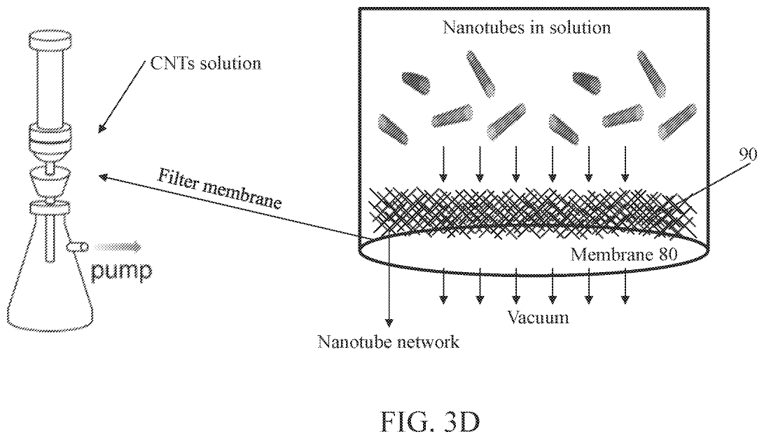

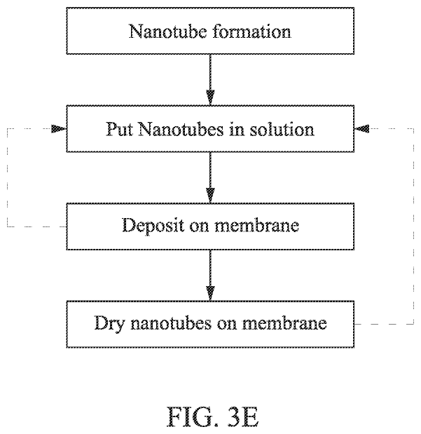

FIGS. 3A, 3B and 3C show the manufacturing of nanotube network membranes for a pellicle in accordance with embodiments of the present disclosure.

In some embodiments, carbon nanotubes are formed by a chemical vapor deposition (CVD) process. In some embodiments, a CVD process is performed by using a vertical furnace as shown in FIG. 3A, and synthesized nanotubes are deposited on a support membrane 80 as shown in FIG. 3B. In some embodiments, carbon nanotubes are formed from a carbon source gas (precursor) using an appropriate catalyst, such as Fe or Ni. Then, the network membrane 100 formed over the support membrane 80 is detached from the support membrane 80, and transferred on to the pellicle frame 15 as shown in FIG. 3C. In some embodiments, a stage or a susceptor, on which the support membrane 80 is disposed, rotates continuously or intermittently (step-by-step manner) so that the synthesized nanotubes are deposited on the support membrane with different or random directions.

FIG. 3D shows a manufacturing process of a network membrane and FIG. 3E shows a flow chart thereof in accordance with an embodiment of the present disclosure.

In some embodiments, carbon nanotubes are dispersed in a solution as shown in FIG. 3D. The solution includes a solvent, such as water or an organic solvent, and a surfactant, such as sodium dodecyl sulfate (SDS). The nanotubes are one type or two or more types of nanotubes (material and/or wall numbers). In some embodiments, carbon nanotubes are formed by various methods, such as arc-discharge, laser ablation or chemical vapor deposition (CVD) methods.

As shown in FIG. 3D, a support membrane 80 is placed between a chamber or a cylinder in which the nanotube dispersed solution is disposed and a vacuum chamber. In some embodiments, the support membrane is an organic or inorganic porous or mesh material. In some embodiments, the support membrane is a woven or non-woven fabric. In some embodiments, the support membrane has a circular shape in which a pellicle size of a 150 mm×150 mm square (the size of an EUV mask) can be placed.

As shown in FIG. 3D, the pressure in the vacuum chamber is reduced so that a pressure is applied to the solvent in the chamber or cylinder. Since the mesh or pore size of the support membrane is sufficiently smaller than the size of the nanotubes, the nanotubes are captured by the support membrane while the solvent passes through the support membrane. The support membrane on which the nanotubes are deposited is detached from the filtration apparatus of FIG. 3D and then is dried. In some embodiments, the deposition by filtration is repeated so as to obtain a desired thickness of the nanotube network layer as shown in FIG. 3E. In some embodiments, after the deposition of the nanotubes in the solution, other nanotubes are dispersed in the same or new solution and the filter-deposition is repeated. In other embodiments, after the nanotubes are dried, another filter-deposition is performed. In the repetition, the same type of nanotubes is used in some embodiments, and different types of nanotubes are used in other embodiments. In some embodiments, the nanotubes dispersed in the solution include multiwall nanotubes.

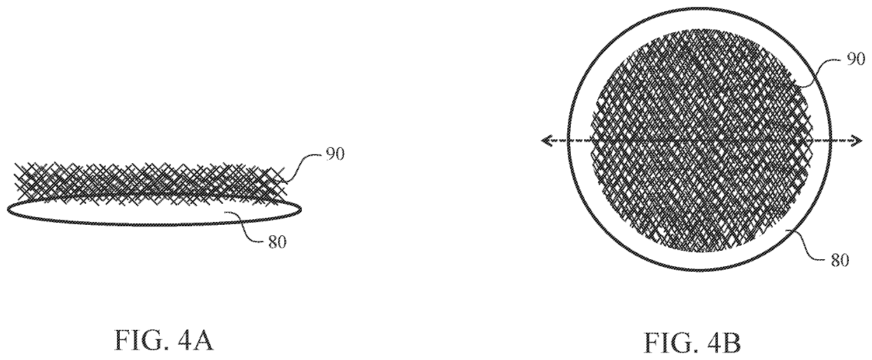

FIGS. 4A and 4B to 6A and 6B show cross sectional views (the “A” figures) and plan (top) views (the “B” figures) of the various stages for manufacturing a pellicle for an EUV photo mask in accordance with an embodiment of the present disclosure. It is understood that additional operations can be provided before, during, and after the processes shown by FIGS. 4A-6B, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

As shown in FIGS. 4A and 4B, a nanotube layer 90 is formed on a support membrane by one or more method as explained above. In some embodiments, the nanotube layer 90 includes single wall nanotubes, multi wall nanotubes, or mixtures thereof. In some embodiments, the nanotube layer 90 includes single wall nanotubes only. In some embodiments, the nanotubes are carbon nanotubes.

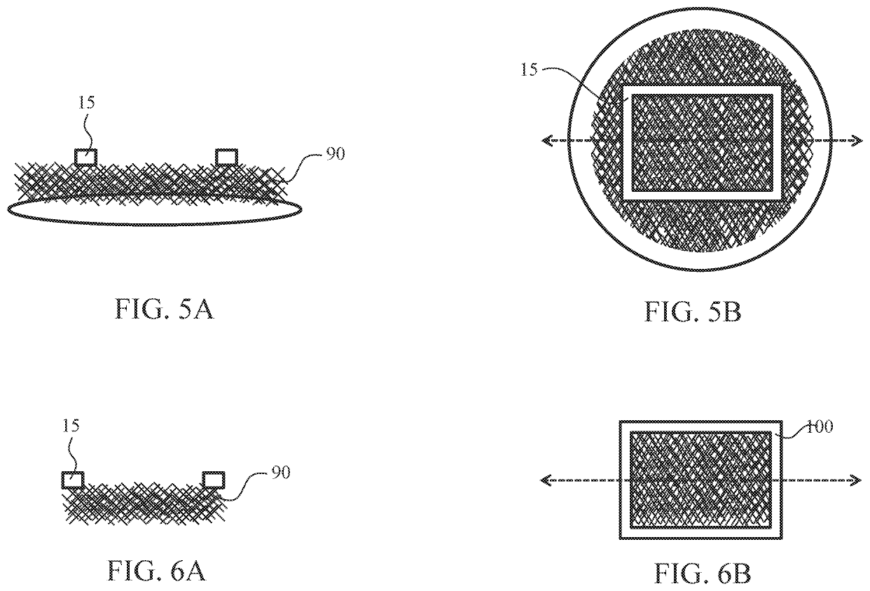

Then, as shown in FIGS. 5A and 5B, a pellicle frame 15 is attached to the nanotube layer 90. In some embodiments, the pellicle frame 15 is formed of one or more layers of crystalline silicon, polysilicon, silicon oxide, silicon nitride, ceramic, metal or organic material. In some embodiments, as shown in FIG. 5B, the pellicle frame 15 has a rectangular (including square) frame shape, which is larger than the black border area of an EUV mask and smaller than the substrate of the EUV mask.

Next, as shown in FIGS. 6A and 6B, the nanotube layer 90 and the support membrane 80 are cut into a rectangular shape having the same size as or slightly larger than the pellicle frame 15, and then the support membrane 80 is detached or removed, in some embodiments. When the support membrane 80 is made of an organic material, the support membrane 80 is removed by wet etching using an organic solvent.

In some embodiments of the present disclosure, a pellicle membrane including a plurality of carbon nanotubes is subjected to a heat (anneal) treatment to remove contaminants, such as residual catalysts (e.g., iron catalyst) used to form nanotubes and to form a plurality of bundles of nanotubes in each of which the nanotubes are closely attached to each other.

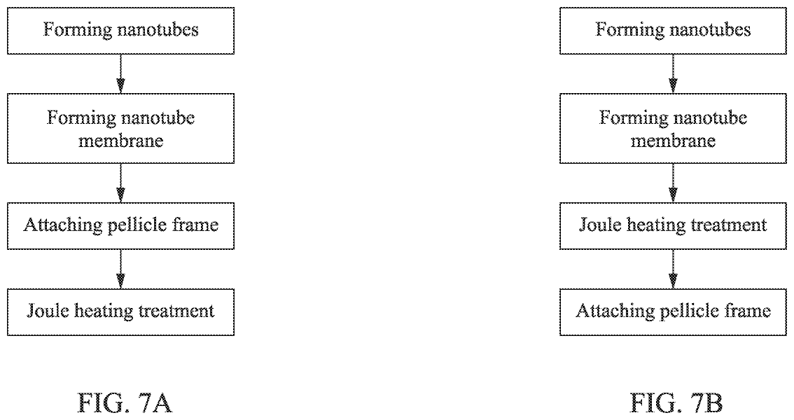

FIGS. 7A and 7B are flow charts showing a treatment process according to embodiments of the present disclosure. It is understood that additional operations can be provided before, during, and after the processes shown in FIGS. 7A and 7B, and some of the operations described below can be replaced or eliminated, for additional embodiments of the method. The order of the operations/processes may be interchangeable.

In the flow of FIG. 7A, as the processes described above, nanotubes are formed, and a membrane is formed by the nanotubes. Then, as set forth, a pellicle frame is attached to the membrane. Subsequently, a heating treatment is performed on the membrane. In the flow shown in FIG. 7B, before the pellicle frame is attached to the membrane, the membrane is subjected to the heating treatment.

In some embodiments, the heating treatment includes a Joule heating treatment, in which a current is applied to pass through the membrane to generate heat, using a Joule heating apparatus as described below.

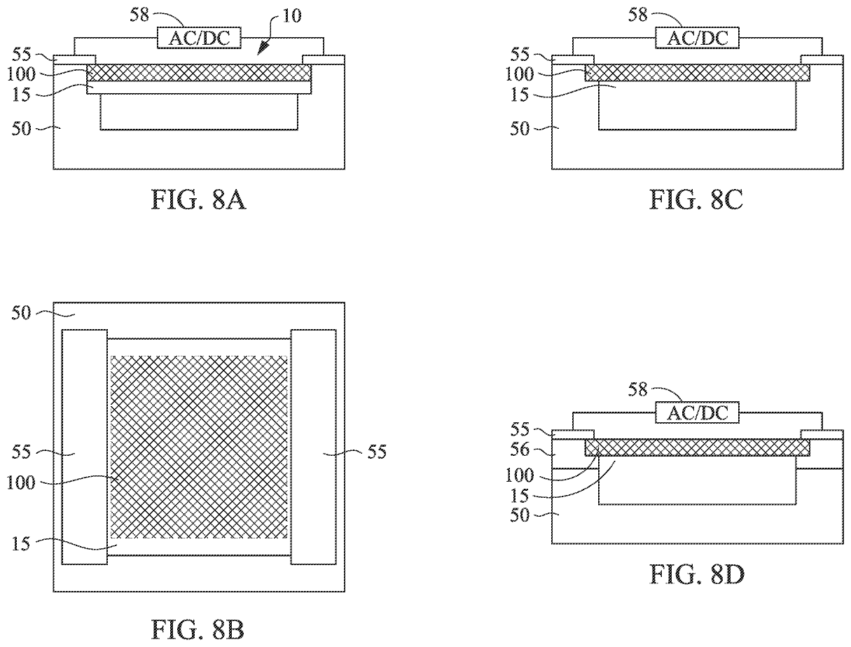

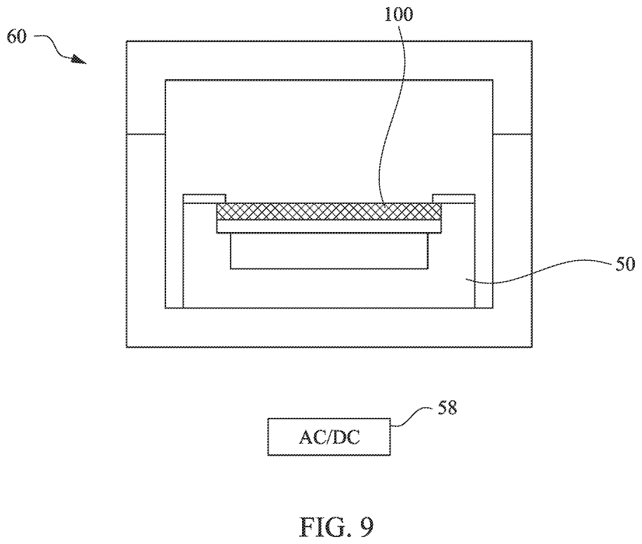

FIGS. 8A, 8B, 8C and 8D show various views of a Joule heating apparatus and process for a pellicle or a pellicle membrane, and FIG. 9 shows a schematic view of a Joule heating apparatus and process for a pellicle or a pellicle membrane in accordance with an embodiment of the present disclosure. FIGS. 8A, 8C and 8D are cross sectional views and FIG. 8B is a plan view (top view).

In some embodiments, as shown in FIGS. 8A and 8B, a pellicle 10 including the membrane 100 and frame 15 is placed over an insulating stage or support 50 and is clamped at the edge portions of the pellicle by parts of the stage and electrodes 55. The insulating stage 50 is made of ceramic in some embodiments, and the electrodes 55 are made of metal, such as tungsten, copper or steel. The electrodes 55 are attached to contact the membrane 100. In some embodiments, the electrodes 55 are attached to two side portions (e.g., left and right) of the membrane 100. In some embodiments, the length of the electrodes are greater than the length of the sides of the pellicle 100 (frame 15). In some embodiments, the pellicle 100 is horizontally supported. In some embodiments, the electrodes 55 are connected to a current source (power supply) 58 by wires.

In other embodiments, as shown in FIG. 8C, when the membrane 100 without a frame 15 is heated, the Joule heating apparatus clamps the membrane at the edge portions, and the electrodes 55 contacts the membrane 100. In some embodiments, as shown in FIG. 8D, the membrane 100 is clamped by two electrodes 55 and 56.

The Joule heating apparatus on which the pellicle 10 or the membrane 100 is mounted is placed in a vacuum chamber 60 as shown in FIG. 9. In some embodiments, the vacuum chamber 60 includes a bottom part in which the Joule heating apparatus is placed and an upper (lid) part, and a gasket (e.g., O-ring) is disposed between the bottom part and the upper part. The wires of the Joule heating apparatus are connected to outside wires, which are connected to the power supply 58.

In the Joule heating operation, the vacuum chamber is evacuated to a pressure equal to or lower than 10 Pa in some embodiments. In some embodiments, the pressure is more than Pa. The power supply 58 applies current to the membrane 100 so that the current passes through the membrane generating heat. In some embodiments, the current is DC, and in other embodiments, the current is AC or pulse current.

In some embodiments, the current from the power supply 58 is adjusted such that the membrane is heated at a temperature in a range from about 800° C. to 2000° C. In some embodiments, the lower limit of the temperature is about 1000° C., 1200° C. or 1500° C., and the upper limit is about 1500° C., 1600° C. or 1800° C. The temperature is adjusted so that metal particles (e.g., iron as residual catalyst) is vaporized under the vacuum and evacuated. When the temperature is lower than these ranges, the contaminant may not be fully removed, and when the temperature is higher than these ranges, the membrane and/or frame may be damaged. In some embodiments, the pellicle frame 15 is made of ceramic or a metal or metallic material having a higher electric resistance than the carbon nanotube membrane 100.

In some embodiments, the Joule heating treatment is performed in an inert gas ambient, such as N₂ and/or Ar. In some embodiments, the Joule heating treatment is performed for about five seconds to about 60 minutes, and is performed to about 30 seconds to about 15 minutes in other embodiments. When the heating time is shorter than these ranges, the contaminant may not be fully removed, and when the heating time is longer than these ranges, a cycle time or a process efficiency may be degraded.

In some embodiments, as shown in FIG. 8B, the electrodes 55 contact two sides (left and right) of the pellicle 10 and the current flows through the membrane 100. In other embodiments, after the heat treatment with the electrodes 55 contacting the two sides (left and right), the pellicle 10 or membrane 100 is rotated by 90 degrees so that the electrodes 55 contact other two sides (top and bottom) of the pellicle for the current to flow through the membrane 100 in the different directions. In some embodiments, an additional pair of electrodes are provided so that top and bottom edges of the pellicle 10 or membrane 100 are also clamped, and a current is switched to flow between the first pair of electrodes or the second (additional) pair of electrodes.

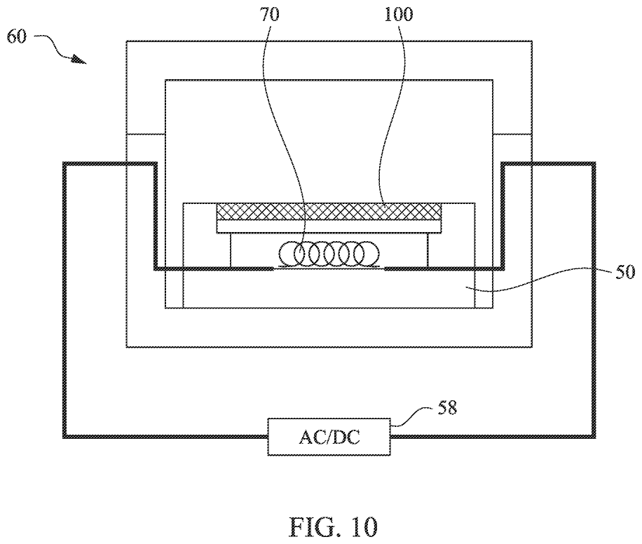

In some embodiments, a Joule heating process is performed using induction heating as shown in FIG. 10. In some embodiments, one or more coils 70 are provided around (e.g., below) the pellicle 10 or membrane 100, and an alternate current is provided to the coils. In some embodiments, the coil is provided outside the vacuum chamber to surround the vacuum chamber. The vacuum chamber is made of glass or ceramic in some embodiments.

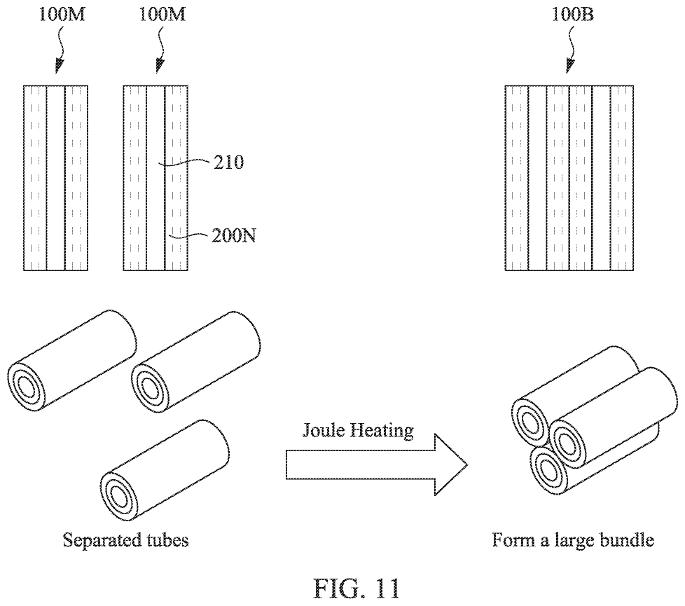

In some embodiments, as shown in FIG. 11, the Joule heating operation causes single separated nanotubes (single or multi wall nanotubes) to join and form a bundle of nanotubes 100B having a seamless graphitic structure, in which the nanotubes are firmly bonded or joined more than merely contacting each other. In some embodiments, three or more nanotubes are connected (bonded or joined) to form a bundle of nanotubes. The number of nanotubes in one bundle is up to 10, in some embodiments.

In some embodiments, the carbon nanotube membrane 100 as formed before the Joule heating treatment includes no or a small number of bundles of nanotubes, and after the Joule heating treatment, the number of the bundles of carbon nanotubes increases.

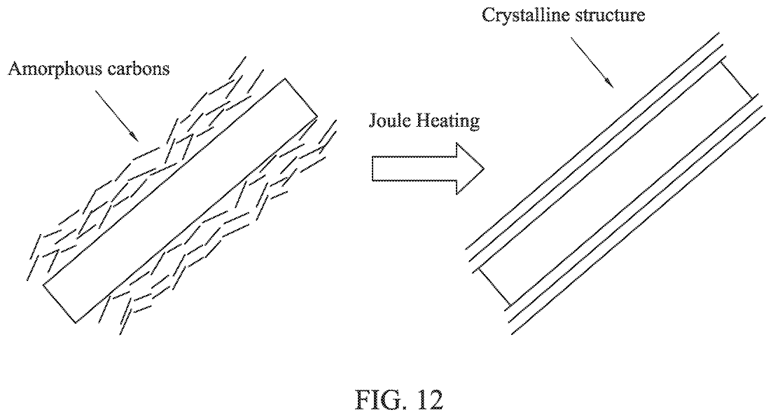

In some embodiments, the carbon nanotube membrane 100 as formed before the Joule heating treatment includes Sp 3 carbon structure, such as amorphous carbon. As shown in FIG. 12, the Joule heating treatment removes the amorphous carbon from the membrane, and/or coverts the amorphous carbon (Sp 3 carbon structure) to a Sp 2 carbon structure. In some embodiments, the amorphous carbon is graphitized to form a crystalline structure. In some embodiments, the crystallized amorphous carbon forms one or more outer tubes surrounding an inner carbon nanotube, which has a single or multi wall structure, to form a multiwall nanotube. In some embodiments, an amount of the amorphous carbon in the membrane as formed before the Joule heating is in a range from about 1 wt % to about 50 wt %, and an amount of the amorphous carbon in the membrane after the Joule heating is less than about 3 wt %. In some embodiments, the amount of the amorphous carbon in the membrane after the Joule heating in a range from about 0.5 wt % to about 2.5 wt %. In some embodiments, all the Sp³ carbon structures are removed or converted, and thus the membrane after the Joule heating treatment show no peak at the D-band (1360 cm⁻¹) in a Raman spectroscopy. In other embodiments, a part of the Sp³ carbon structures remains, and a light peak at the D-band is observed.

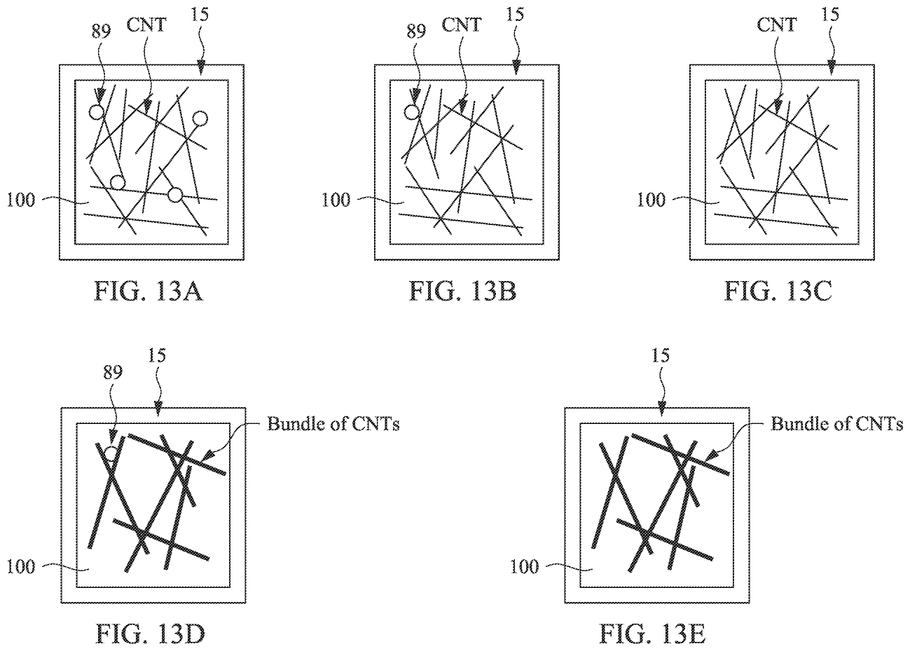

FIGS. 13A-13E shows schematic views illustrating catalyst removal and bundle formation by the Joule heating treatment according to embodiments of the present disclosure.

As set forth above, a carbon nanotube membrane 100 (with or without a pellicle frame 15) may include residual catalyst or catalyst particles 89 therein as shown in FIG. 13A. The Joule heating treatment can remove a part of (see FIG. 13B) or all of (see FIG. 13C) the residual catalysts from the membrane. In addition, separate nanotubes as shown in FIG. 13A can be converted by the Joule heating treatment to bundles of nanotubes as shown in FIGS. 13D and 13E. In some embodiments, an amount of the residual catalysts in the membrane as formed before the Joule heating is in a range from about 7 wt % to about 15 wt %, and an amount of the residual catalysts in the membrane after the Joule heating is less than about 2 wt %. In some embodiments, the amount of the residual catalysts in the membrane after the Joule heating is in a range from about 0.1 wt % to about 1.5 wt %.

As set forth above, the Joule heating treatment can improve chemical and mechanical properties of a network membrane formed by carbon nanotubes.

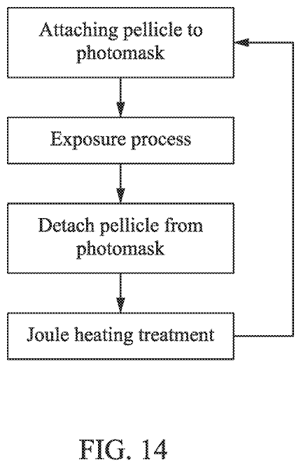

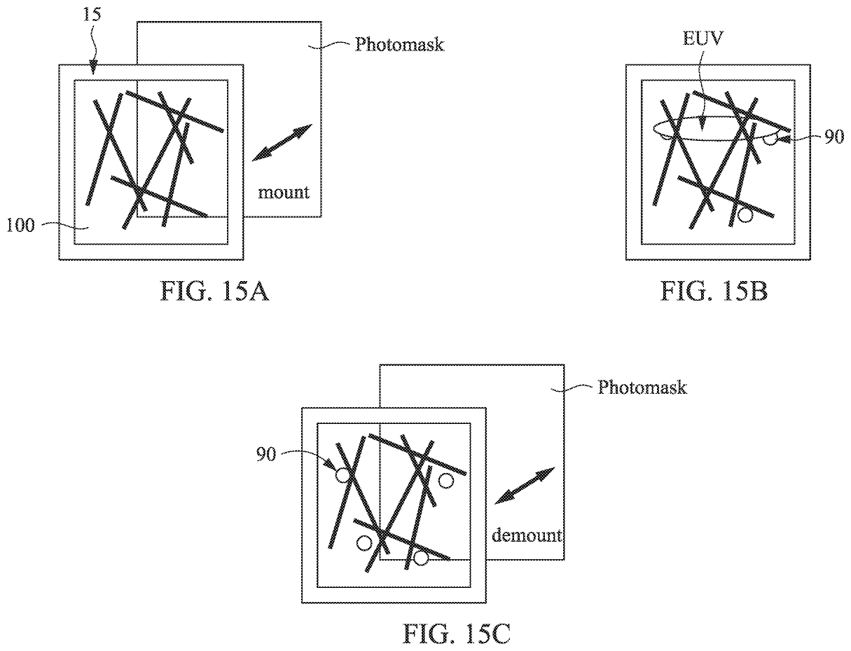

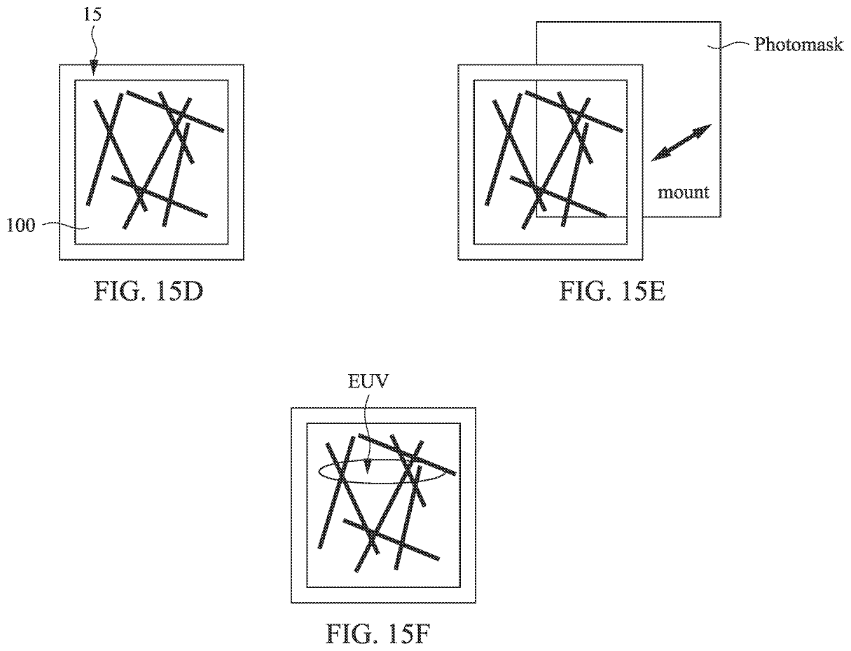

FIG. 14 shows a flow chart for treating a pellicle for an EUV photo mask and FIGS. 15A-15E show schematic views of treating the pellicle in accordance with embodiments of the present disclosure. It is understood that additional operations can be provided before, during, and after the processes shown in FIGS. 14 and 15A-15E, and some of the operations described below can be replaced or eliminated, for additional embodiments of the method. The order of the operations/processes may be interchangeable.

In some embodiments, the Joule heating treatment is performed after the pellicle is used in EUV lithography operations.

As shown in FIG. 14 and FIG. 15A, a pellicle with a frame that has been subjected to the Joule heating treatment as shown in FIGS. 7A and 7B is attached to an EUV photomask. Then, the photomask is used in EUV lithography operations subjected to EUV radiation. During the EUV lithography operation, contaminants or particles 90 may fall on the pellicle as shown in FIG. 15B. In some embodiments, the contaminant or particles include particles of Mo, SiC, TiN, Ta, Fe, Ni and others. After the predetermined number of EUV exposure operations are performed, the pellicle is demounted from the photomask as shown in FIG. 15C, and the pellicle is subjected to the Joule heating treatment as described above to remove the contaminants and particles, as shown in FIG. 15D. In some embodiments, one or more defects caused by EUV radiation in the carbon nanotube membrane are removed or reduced by graphitization during the Joule heating treatment. In some embodiments, an additional wet or dry cleaning is performed before or after the Joule heating treatment. Then, the pellicle is mounted again to an EUV photo mask as shown in FIG. 15E, and the photomask is used in EUV lithography operations as shown in FIG. 15F.

In some embodiments, the network membrane includes Sp 2 carbon structure, such as graphite or graphene in the alternative or in addition to carbon nanotubes.

In some embodiments, the pellicle of the present embodiments further includes one or more cover layers. The cover layer(s) is attached to the membrane after the initial Joule heating treatment is performed.

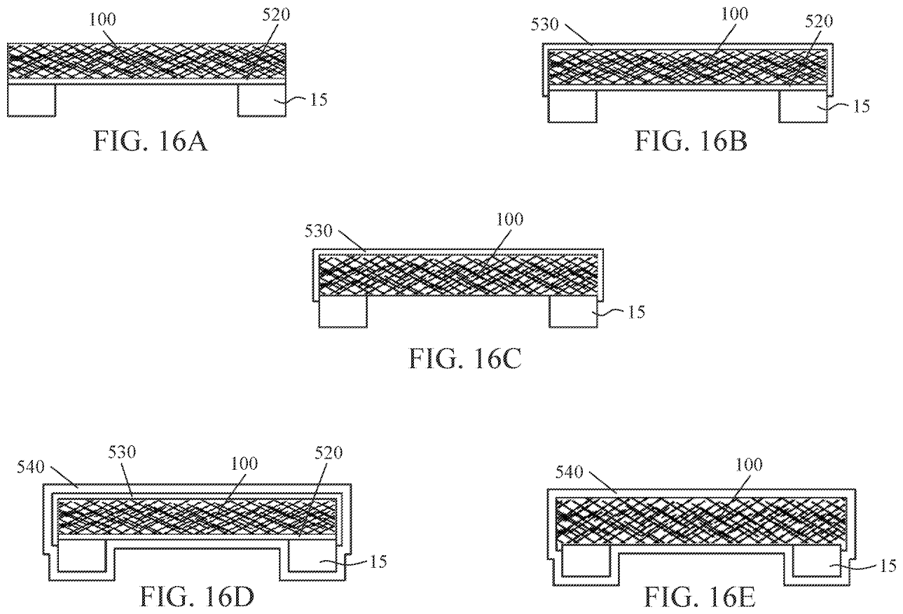

In some embodiments, a first cover sheet (or layer) 520 is formed at the bottom surface of the network membrane 100 between the frame 15 and the network membrane 100 as shown in FIG. 16A. In some embodiments, a second cover sheet 530 is formed over the network membrane 100 to seal the network membrane together with the first cover sheet 520, as shown in FIG. 16B. In some embodiments, no first cover sheet is used and only the second cover sheet 530 is used as show in FIG. 16C. In some embodiments, a third cover sheet 540 covers the entire structure of FIG. 16B (or FIG. 16A or 16C), as shown in FIG. 16D. In some embodiment, no first cover sheet and/or second cover sheet are used as shown in FIG. 16E. In some embodiments, the material of the third cover sheet 540 of FIG. 16E is the same as the material of the first and/or second cover sheets.

In some embodiments, one of or both of the first cover layer 520 and the second cover layer 530 include a two-dimensional material in which one or more two-dimensional layers are stacked. Here, a “two-dimensional” layer refers to one or a few crystalline layers of an atomic matrix or a network having thickness within the range of about 0.1-5 nm, in some embodiments. In some embodiments, the two-dimensional materials of the first cover layer 520 and the second cover layer 530 are the same or different from each other. In some embodiments, the first cover layer 520 includes a first two-dimensional material and the second cover layer 530 includes a second two-dimensional material.

In some embodiments, the two-dimensional material for the first cover layer 520 and/or the second cover layer 530 includes at least one of boron nitride (BN), graphene, and/or transition metal dichalcogenides (TMDs), represented by MX₂, where M=Mo, W, Pd, Pt, and/or Hf, and X=S, Se and/or Te. In some embodiments, a TMD is one of MoS₂, MoSe₂, WS₂ or WSe₂.

In some embodiments, a total thickness of each of the first cover layer 520 and the second cover layer 530 is in a range from about 0.3 nm to about 3 nm and is in a range from about 0.5 nm to about 1.5 nm in other embodiments. In some embodiments, a number of the two-dimensional layers of each of the two-dimensional materials of the first and/or second cover layers is 1 to about 20, and is 2 to about 10 in other embodiments. When the thickness and/or the number of layers is greater than these ranges, EUV transmittance of the pellicle may be decreased and when the thickness and/or the number of layers is smaller than these ranges, mechanical strength of the pellicle may be insufficient.

In some embodiments, a third cover layer 540 includes at least one layer of an oxide, such as HfO₂, Al₂O₃, ZrO₂, Y₂O₃, or La₂O₃. In some embodiments, the third cover layer 540 includes at least one layer of non-oxide compounds, such as B₄C, YN, Si₃N₄, BN, NbN, RuNb, YF₃, TiN, or ZrN. In some embodiments, the protection layer 40 includes at least one metal layer made of, for example, Ru, Nb, Y, Sc, Ni, Mo, W, Pt, or Bi. In some embodiments, the third cover layer 540 is a single layer, and in other embodiments, two or more layers of these materials are used as the third cover layer 540. In some embodiments, a thickness of the third cover layer is in a range from about 0.1 nm to about 5 nm, and is in a range from about 0.2 nm to about 2.0 nm in other embodiments. When the thickness of the third cover layer 540 is greater than these ranges, EUV transmittance of the pellicle may be decreased and when the thickness of the third cover layer 540 is smaller than these ranges, the mechanical strength of the pellicle may be insufficient.

In some embodiments, the thickness of the network membrane 100 is in a range from about 5 nm to about 100 nm, and is in a range from about 10 nm to about 50 nm in other embodiments. When the thickness of the network membrane 100 is greater than these ranges, EUV transmittance may be decreased and when the thickness of the network membrane 100 is smaller than these ranges, the mechanical strength may be insufficient.

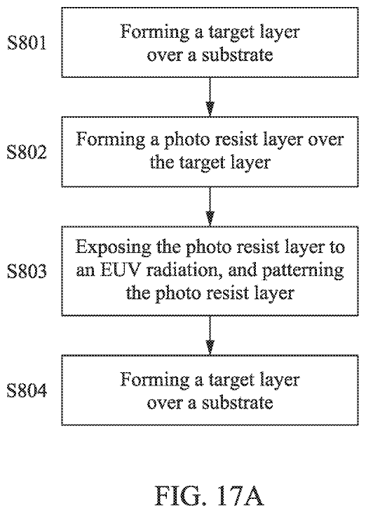

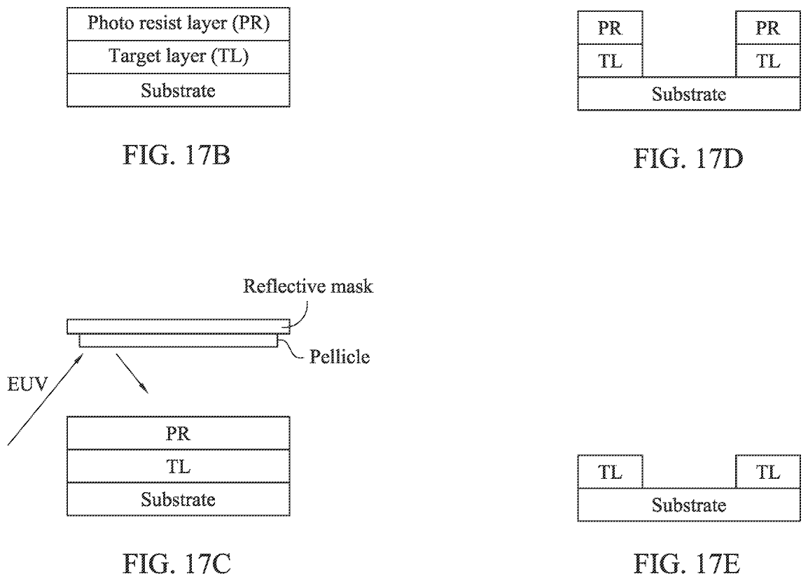

FIG. 17A shows a flowchart of a method of making a semiconductor device, and FIGS. 17B, 17C, 17D and 17E show a sequential manufacturing method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S801 of FIG. 17A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. At S802, of FIG. 17A, a photo resist layer is formed over the target layer, as shown in FIG. 17B. The photo resist layer is sensitive to the radiation from the exposing source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer. At S803 of FIG. 17A, the photo resist layer is patterned using an EUV reflective mask with a pellicle as set forth above, as shown in FIG. 17C. The patterning of the photo resist layer includes performing a photolithography exposing process by an EUV exposing system using the EUV mask. During the exposing process, the integrated circuit (IC) design pattern defined on the EUV mask is imaged to the photo resist layer to form a latent pattern thereon. The patterning of the photo resist layer further includes developing the exposed photo resist layer to form a patterned photo resist layer having one or more openings. In one embodiment where the photo resist layer is a positive tone photo resist layer, the exposed portions of the photo resist layer are removed during the developing process. The patterning of the photo resist layer may further include other process steps, such as various baking steps at different stages. For example, a post-exposure-baking (PEB) process may be implemented after the photolithography exposing process and before the developing process.

At S804 of FIG. 17A, the target layer is patterned utilizing the patterned photo resist layer as an etching mask, as shown in FIG. 17D. In some embodiments, the patterning the target layer includes applying an etching process to the target layer using the patterned photo resist layer as an etch mask. The portions of the target layer exposed within the openings of the patterned photo resist layer are etched while the remaining portions are protected from etching. Further, the patterned photo resist layer may be removed by wet stripping or plasma ashing, as shown in FIG. 17E.

In some embodiments, the network membrane including carbon nanotubes or other Sp2 carbons subjected to the Joule heating treatment is used for an EUV transmissive window, a debris catcher disposed between an EUV lithography apparatus and an EUV radiation source, or any other parts in an EUV lithography apparatus and an EUV radiation, where a high EUV transmittance is required.

In the foregoing embodiments, a pellicle membrane is subjected to a Joule heating operation to remove contaminants and to form bundles of carbon nanotubes. The pellicles according to embodiments of the present disclosure provide higher strength and lower contamination as well as higher EUV transmittance than conventional pellicles.

It will be understood that not all advantages have been necessarily discussed herein, no particular advantage is required for all embodiments or examples, and other embodiments or examples may offer different advantages.

In accordance with one aspect of the present disclosure, in a method of manufacturing a pellicle for an extreme ultraviolet (EUV) photomask, a nanotube layer including a plurality of carbon nanotubes is formed, the nanotube layer is attached to a pellicle frame, and a Joule hearting treatment is performed to the nanotube layer by applying electric current through the nanotube layer. In one or more of the foregoing and following embodiments, the Joule heating treatment is performed under a pressure equal to or less than 10 Pa. In one or more of the foregoing and following embodiments, the Joule heating treatment is performed at an inert gas ambient. In one or more of the foregoing and following embodiments, the Joule heating treatment is performed for five seconds to 60 minutes. In one or more of the foregoing and following embodiments, the electric current is applied such that the nanotube layer is heated at a temperature in a range from 800° C. to 2000° C. In one or more of the foregoing and following embodiments, the electric current is DC. In one or more of the foregoing and following embodiments, the electric current is AC. In one or more of the foregoing and following embodiments, the Joule heating treatment is performed by: placing the nanotube layer with the pellicle frame on a support, clamping edges of the frame with conductive plates so that the conductive plates contact the nanotube layer, and applying the electric current through the conductive plates. In one or more of the foregoing and following embodiments, before or after the clamping, the nanotube layer is placed in a vacuum chamber. In one or more of the foregoing and following embodiments, the plurality of carbon nanotubes include metallic contaminant, an amount of the metallic contaminants in the nanotube layer after the Joule heating treatment is smaller than an amount of the metallic contaminants in the nanotube layer. In one or more of the foregoing and following embodiments, the metallic contaminants include iron catalysts used in forming the plurality of carbon nanotubes. In one or more of the foregoing and following embodiments, the metallic contaminants include one or more of Mo, Ti, TiN, Ta or Ni.

In accordance with another aspect of the present disclosure, in a method of manufacturing a pellicle for an extreme ultraviolet (EUV) photomask, a nanotube layer including the plurality of carbon nanotubes and amorphous carbon is formed, the nanotube layer is attached to a pellicle frame, and a Joule hearting treatment is performed to the nanotube layer by applying electric current. At least a part of the amorphous carbon is converted to crystal by the Joule heating treatment. In one or more of the foregoing and following embodiments, the crystallized amorphous carbon has a graphite structure. In one or more of the foregoing and following embodiments, the crystallized amorphous carbon is formed on a surface of a carbon nanotube in the plurality of carbon nanotube. In one or more of the foregoing and following embodiments, the crystallized amorphous carbon formed on the surface of the carbon nanotube has a multilayer structure. In one or more of the foregoing and following embodiments, at least a part of the amorphous carbon is removed by the Joule heating treatment.

In accordance with another aspect of the present disclosure, in a method of manufacturing a pellicle for an extreme ultraviolet (EUV) photomask, a nanotube layer including the plurality of carbon nanotubes is formed, the nanotube layer is attached to a pellicle frame, and a Joule hearting treatment is performed to the nanotube layer by applying electric current. After the Joule heating treatment, the nanotube layer includes a plurality of bundles of carbon nanotubes, in each of which the carbon nanotubes are connected to form a seamless graphite structure. In one or more of the foregoing and following embodiments, a number of the plurality of bundles of carbon nanotubes increases by the Joule heating treatment. In one or more of the foregoing and following embodiments, the carbon nanotubes of the plurality of bundles include multiwall nanotubes. In one or more of the foregoing and following embodiments, a number of the carbon nanotubes in one bundle is three or more.

In accordance with another aspect of the present disclosure, in a method of an extreme ultraviolet (EUV) lithography, an EUV pellicle is attached to an EUV photomask, an EUV exposure process using the EUV photomask with the EUV pellicle is performed, the EUV pellicle is detached from the EUV photomask, and a Joule heating treatment is performed on the EUV pellicle by applying electric current through the EUV pellicle. In one or more of the foregoing and following embodiments, the EUV pellicle includes a nanotube layer comprising a plurality of nanotubes. In one or more of the foregoing and following embodiments, the plurality of nanotubes comprises carbon nanotubes. In one or more of the foregoing and following embodiments, the carbon nanotubes comprises multiwall nanotubes. In one or more of the foregoing and following embodiments, the EUV pellicle includes contaminant, and an amount of the contaminants in the EUV pellicle after the Joule heating treatment is smaller than an amount of the contaminants in the EUV pellicle. In one or more of the foregoing and following embodiments, the contaminants include one or more of Mo, SiC, Si, Ti, TiN, Ta, Fe or Ni.

In accordance with another aspect of the present disclosure, in a method of treating a membrane that transmits extreme ultraviolet (EUV) light, the membrane comprises Sp 2 carbon and a Joule hearting treatment is performed to the membrane by applying electric current through the membrane. In one or more of the foregoing and following embodiments, before the Joule heating treatment, the membrane is attached to a frame having an opening. In one or more of the foregoing and following embodiments, the frame is a pellicle frame. In one or more of the foregoing and following embodiments, after the Joule heating treatment, the pellicle frame is attached to an EUV photomask. In one or more of the foregoing and following embodiments, the membrane comprises at least one of carbon nanotube, graphene, or graphite. In one or more of the foregoing and following embodiments, the membrane before the Joule heating treatment further comprises Sp 3 carbon, and at least a part of the Sp 3 carbon is covered to Sp 2 carbon by the Joule heating treatment. In one or more of the foregoing and following embodiments, the membrane comprises carbon nanotubes, after the Joule heating treatment, the membrane includes a plurality of bundles of carbon nanotubes, in each of which the carbon nanotubes are connected to form a seamless graphite structure. In one or more of the foregoing and following embodiments, before the Joule heating treatment, the membrane includes a plurality of bundles of carbon nanotubes, and a number of the plurality of bundles of carbon nanotubes after the Joule heating treatment is greater than a number of the plurality of bundles of carbon nanotubes before the Joule heating treatment. In one or more of the foregoing and following embodiments, an EUV transmittance of the membrane is 95% to 98%.

In accordance with another aspect of the present disclosure, an EUV pellicle includes a network membrane including a plurality of carbon nanotubes, and residual catalyst particles in an amount of less than 2 wt % with respect to a total weight of the network membrane. In accordance with another aspect of the present disclosure, an EUV pellicle includes a network membrane including a plurality of carbon nanotubes and amorphous carbon, and an amount of amorphous carbon in the network membrane is less than 3 wt % with respect to a total weight of the network membrane.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing a pellicle for an extreme ultraviolet (EUV) photomask, comprising:
forming a nanotube layer including a plurality of carbon nanotubes;
attaching the nanotube layer to a pellicle frame; and
performing a Joule heating treatment to the nanotube layer by applying electric current through the nanotube layer.

2. The method of claim 1, wherein the Joule heating treatment is performed under a pressure equal to or less than 10 Pa.

3. The method of claim 2, wherein the Joule heating treatment is performed in an inert gas ambient for five seconds to 60 minutes.

4. The method of claim 1, wherein the electric current is applied such that the nanotube layer is heated at a temperature in a range from 800° C. to 2000° C.

5. The method of claim 4, wherein the electric current is DC.

6. The method of claim 4, wherein the electric current is AC.

7. The method of claim 1, wherein the Joule heating treatment is performed by:
placing the nanotube layer with the pellicle frame on a support;
clamping edges of the pellicle frame with conductive plates so that the conductive plates contact the nanotube layer; and
applying the electric current through the conductive plates.

8. The method of claim 7, wherein before or after the clamping, the nanotube layer is placed in a vacuum chamber.

9. The method of claim 1, wherein:
the plurality of carbon nanotubes include metallic contaminants, and
an amount of the metallic contaminants in the nanotube layer after the Joule heating treatment is smaller than an amount of the metallic contaminants in the nanotube layer before the Joule heating treatment.

10. The method of claim 9, wherein the metallic contaminants include iron catalysts used in forming the plurality of carbon nanotubes.

11. The method of claim 9, wherein the metallic contaminants include one or more of Mo, Ti, TiN, Ta or Ni.

12. A method of manufacturing a pellicle for an extreme ultraviolet (EUV) photomask, comprising:
forming a nanotube layer including a plurality of carbon nanotubes and amorphous carbon;
attaching the nanotube layer to a pellicle frame; and
performing a Joule heating treatment to the nanotube layer by applying electric current,
wherein at least a part of the amorphous carbon is converted to crystallized amorphous carbon by the Joule heating treatment.

13. The method of claim 12, wherein the crystallized amorphous carbon has a graphite structure.

14. The method of claim 12, wherein the crystallized amorphous carbon is formed on a surface of a carbon nanotube in the plurality of carbon nanotube.

15. The method of claim 14, wherein the crystallized amorphous carbon formed on the surface of the carbon nanotube has a multilayer structure.

16. The method of claim 12, wherein at least a part of the amorphous carbon is removed by the Joule heating treatment.

17. A method of manufacturing a pellicle for an extreme ultraviolet (EUV) photomask, comprising:
forming a nanotube layer including a plurality of carbon nanotubes;
attaching the nanotube layer to a pellicle frame; and
performing a Joule heating treatment to the nanotube layer by applying electric current,
wherein after the Joule heating treatment, the nanotube layer includes a plurality of bundles of carbon nanotubes, in each of which the carbon nanotubes are connected to form a seamless graphite structure.

18. The method of claim 17, wherein a number of the plurality of bundles of carbon nanotubes increases by the Joule heating treatment.

19. The method of claim 17, wherein the carbon nanotubes of the plurality of bundles of carbon nanotubes include multiwall nanotubes.

20. The method of claim 17, wherein a number of the carbon nanotubes in one bundle of carbon nanotubes is three or more.
